(19) United States
(12) Patent Application Publication
(10) Pub. No.: US 2022/0224315 A1
(43) Pub. Date: Jul. 14, 2022

(54) LATCH AND ISOLATION CIRCUITS

(71) Applicant: 2Pai Semiconductor Co., Limited, Shanghai (CN)

(72) Inventor: Zhiwei Dong, Shanghai (CN)

(73) Assignee: 2Pai Semiconductor Co., Limited, Shanghai (CN)

(21) Appl. No.: 17/711,589

(22) Filed: Apr. 1, 2022

Related U.S. Application Data
(63) Continuation-in-part of application No. 16/002,949, filed on Jun. 7, 2018.

(30) Foreign Application Priority Data
Jan. 10, 2018 (CN) 201810024553.9

(51) Int. Cl. H03K 3/0233

(52) U.S. Cl. CPC H03K 3/0233

(57) ABSTRACT

A latch circuit includes a first differential input terminal for receiving a first differential input signal and a second differential input terminal for receiving a second differential input signal. The circuit also includes a first switch comprising a first switch input terminal coupled to the first differential input terminal and a first output terminal, and a second switch comprising a second switch input terminal coupled to the second differential input terminal and a second output terminal. The circuit also includes a first cascade switch coupled to the first output terminal and a second cascade switch coupled to the second output terminal. The first differential input signal is characterized by a swing voltage of less than 300 mV and includes a first pulse component and a first non-zero voltage component, the first non-zero voltage component being attributed at least to the first switch and the first input resistor.

### CROSS-REFERENCES TO RELATED APPLICATIONS

The present invention is a continuation-in-part application to U.S. patent application Ser. No. 16/002,949, entitled “LATCH AND ISOLATION CIRCUIT”, filed on Jun. 7, 2018, which claims priority to Chinese Patent Application No. 201810024553.9, titled “LATCH AND ISOLATION CIRCUIT”, filed on Jan. 10, 2018. Both applications are commonly owned and incorporated herein by reference for all purposes.

### TECHNICAL FIELD

The present disclosure generally relates to electronic circuit technology field.

### BACKGROUND OF THE INVENTION

A latch is a level-sensitive memory device with a main function of latching a logic level of an input signal and maintaining it at a certain level (e.g. logic “0” or logic “1”) stably. Latches are widely applied to various circuits such as isolation circuits, memory circuits or the like.

In a common latch structure including a pair of inverters, two inverters are connected end to end, and each of the two inverters is comprised of a P-type Metal-Oxide-Semiconductor Field-Effect Transistor (MOSFET) and an N-type MOSFET. Specifically, as shown in FIG. 1, a latch 100 having a pair of inverter structure may include a first transistor MP1, a second transistor MN1, a third transistor MP2 and a fourth transistor MN2, where the first transistor MP1 and the second transistor MN1 constitute a first inverter (not shown), and the third transistor MP2 and the fourth transistor MN2 constitute a second inverter (not shown). In practical application, a source (and a substrate) of the first transistor MP1 and a source (and a substrate) of the third transistor MP2 may be connected with a power supply Vdd with a voltage of, for example, 3.3V or 1.8V, and a source (and a substrate) of the second transistor MN1 and a source (and a substrate) of the fourth transistor MN2 may be grounded to Vss generally with a potential of 0V. The latch 100 is a bistable latch having two latching points, one is an in-phase latching point A and the other is an inverting latching point B or vice versa. The logic levels latched by the two latching points are opposite to each other.

A flipping amplitude of a latch represents a voltage amplitude difference between a latched signal being recognized as logic “0” and a latched signal being recognized as logic “1”. The flipping amplitude of the latch 100 in the existing technology generally ranges from 0V to the power supply voltage Vdd, and the latch 100 with a flipping amplitude of 0V to the power supply voltage Vdd can satisfy the application requirements of majority circuits. However, with the continuous development of the integrated circuit technology, the requirements for chip area and process cost become higher and higher. The latch 100 with a flipping amplitude of 0V to the power supply voltage Vdd in the existing technology is gradually unable to meet the performance requirements of a high performance integrated circuit chip.

### BRIEF SUMMARY OF THE INVENTION

In order to reduce the flipping amplitude of the latches in the existing technologies, a latch is provided according to an embodiment of the present disclosure. The latch may include: a first-level substructure and at least one second-level substructure, where the at least one second-level substructure has a number of k, and k is a positive integer greater than or equal to 1; where the first-level substructure may include: a first load having a first terminal coupled with a first port, a second load having a first terminal coupled with the first port, a first driving circuit having a control terminal coupled with a second terminal of the first load and a second terminal coupled with a second port, and a second driving circuit having a control terminal coupled with a second terminal of the second load and a second terminal coupled with the second port; and each of the at least one second-level substructure may include: a third load, a fourth load, a third driving circuit and a fourth driving circuit; in a first second-level substructure, a first terminal of the third load is coupled with the second terminal of the second load, a second terminal of the third load is coupled with a control terminal of the third driving circuit, a first terminal of the first driving circuit and a first terminal of the fourth driving circuit, a first terminal of the fourth load is coupled with the second terminal of the first load, a second terminal of the fourth load is coupled with a control terminal of the fourth driving circuit, a first terminal of the second driving circuit and a first terminal of the third driving circuit, and a second terminal of the third driving circuit and a second terminal of the fourth driving circuit are coupled with a first reference port; and in an i-th second-level substructure, a first terminal of the third load is coupled with a second terminal of the fourth load of an (i−1)-th second-level substructure, a second terminal of the third load is coupled with a control terminal of the third driving circuit, a first terminal of a third driving circuit of the (i−1)-th second-level substructure and a first terminal of the fourth driving circuit, a first terminal of the fourth load is coupled with a second terminal of the third load of the (i−1)-th second-level substructure, a second terminal of the fourth load is coupled with a control terminal of the fourth driving circuit, a first terminal of the fourth driving circuit of the (i−1)-th second-level substructure and a first terminal of the third driving circuit, and a second terminal of the third driving circuit and a second terminal of the fourth driving circuit are coupled with an i-th reference port; where i is a positive integer greater than 1 and less than or equal to k.

In some embodiment, one or more of the first load, the second load, the third load and the fourth load may be resistors.

In some embodiment, the first driving circuit may include a first transistor, a control terminal of the first transistor may serve as the control terminal of the first driving circuit, a first terminal of the first transistor may serve as the first terminal of the first driving circuit, and a second terminal of the first transistor may serve as the second terminal of the first driving circuit; and the second driving circuit may include a second transistor, a control terminal of the second transistor may serve as the control terminal of the second driving circuit, a first terminal of the second transistor may serve as the first terminal of the second driving circuit, and a second terminal of the second transistor may serve as the second terminal of the second driving circuit.

In some embodiment, the first transistor and the second transistor may be N-type MOSFETs; the first port may be a power supply port, the power supply port may be configured to be input with a power supply voltage; a gate of the first transistor may be connected with the second terminal of the first load, a drain of the first transistor may be connected with a second terminal of the third load in a first second-level substructure, and a source of the first transistor may be connected with the second port; and a gate of the second transistor may be connected with the second terminal of the second load, a drain of the second transistor may be connected with the second terminal of the fourth load in the first second-level substructure, and a source of the second transistor may be connected with the second port.

In some embodiment, the first transistor and the second transistor may be bipolar transistors; the first port may be a power supply port, and the power supply port may be configured to be input with a power supply voltage; a base of the first transistor may be connected with the second terminal of the first load, a collector of the first transistor may be connected with the second terminal of the third load in the first second-level substructure, and an emitter of the first transistor may be connected with the second port; and a base of the second transistor may be connected with the second terminal of the second load, a collector of the second transistor may be connected with the second terminal of the fourth load in the first second-level substructure, and an emitter of the second transistor may be connected with the second port.

In some embodiment, the second port may be coupled with an output terminal of a current source.

In some embodiment, the first transistor and the second transistor may be P-type MOSFETs; the first port may be directly or indirectly coupled with a reference ground; a gate of the first transistor may be connected with the second terminal of the first load, a drain of the first transistor may be connected with the second terminal of the second load, and a source of the first transistor may be connected with the second port; and a gate of the second transistor may be connected with the second terminal of the second load, a drain of the second transistor may be connected with the second terminal of the first load, and a source of the second transistor may be connected with the second port.

In some embodiment, the second port may be coupled with an output terminal of a current source.

In some embodiment, the third driving circuit may include a third transistor, a control terminal of the third transistor may serve as the control terminal of the third driving circuit, a first terminal of the third transistor may serve as the first terminal of the third driving circuit, and a second terminal of the third transistor may serve as the second terminal of the third driving circuit; and the fourth driving circuit may include a fourth transistor, a control terminal of the fourth transistor may serve as the control terminal of the fourth driving circuit, a first terminal of the fourth transistor may serve as the first terminal of the fourth driving circuit, and a second terminal of the fourth transistor may serve as the second terminal of the fourth driving circuit.

In some embodiment, the first load and the second load have same or different electrical parameters, the first driving circuit and the second driving circuit have same or different electrical parameters, the third load and the fourth load have same or different electrical parameters, and the third driving circuit and the fourth driving circuit have same or different electrical parameters.

An isolation circuit is also provided according to embodiments of the present disclosure, where the isolation circuit may include the aforementioned latch.

In some embodiment, the isolation circuit may further include a main isolating capacitor, a voltage dividing capacitor and an amplifier; where a first terminal of the main isolating capacitor is coupled with an input terminal of the isolation circuit, and a second terminal of the main isolating capacitor is coupled with a first terminal of the voltage dividing capacitor and the control terminal of the first driving circuit; a second terminal of the voltage dividing capacitor is coupled with a ground terminal; the control terminal of the second driving circuit is coupled with the main isolating capacitor; and an output terminal of the amplifier is coupled with an output terminal of the isolation circuit.

Compared with the existing technology, the present disclosure has the following beneficial effects.

The latch according to embodiments of the present disclosure may include a first-level substructure and at least one second-level substructure, where the at least one second-level substructure has a number of k, k is a positive integer greater than or equal to 1, the first-level substructure may include a first load, a second load, a first driving circuit and a second driving circuit, and the second-level substructure may include a third load, a fourth load, a third driving circuit and a fourth driving circuit. In an i-th second-level substructure, a first terminal of the third load may be coupled with a second terminal of the fourth load of an (i−1)-th second-level substructure, a second terminal of the third load may be coupled with a control terminal of the third driving circuit, a first terminal of a third driving circuit of the (i−1)-th second-level substructure and a first terminal of the fourth driving circuit, a first terminal of the fourth load may be coupled with a second terminal of the third load of the (i−1)-th second-level substructure, a second terminal of the fourth load may be coupled with a control terminal of the fourth driving circuit, a first terminal of the fourth driving circuit of the (i−1)-th second-level substructure and a first terminal of the third driving circuit, and a second terminal of the third driving circuit and a second terminal of the fourth driving circuit may be coupled with an i-th reference port; where i is a positive integer greater than 1 and less than or equal to k. With the above circuit structure, when the latch includes the first-level substructure and a second-level substructure, a flipping amplitude may be determined based on electrical parameters (e.g. impedance values) of the first load, the second load, the third load and the fourth load and electrical parameters (e.g. output current magnitude) of the first driving circuit, the second driving circuit, the third driving circuit and the fourth driving circuit. Further, the flipping amplitude of the latch according to the embodiments of the present disclosure substantially depends on the impedance value of each load and the current of each driving circuit. Since the impedance value of each load and the current of each driving circuit may have a wide design range in practice, the flipping amplitude can be any value from several millivolts to several volts, and can be achieved at any temperature and on any production line based on the process level in the existing technology. In conjunction with the current development trend of integrated circuits, the flipping amplitude of the latch in the present disclosure can meet the performance requirements of high-performance integrated circuits (e.g. isolation circuits).

Further, an isolation circuit is also provided according to embodiments of the present disclosure, which may include the latch according to the embodiments of the present disclosure. Since the flipping amplitude of the latch in the present disclosure may be any value from several millivolts to several volts, the flip energy required to bring the latch into a steady state can be small, and a capacitance of the main isolating capacitor configured to transmit energy in the isolation circuit can be also small. Accordingly, a chip area of the isolation circuit and the cost can be reduced. In addition, a circuit for driving the main isolating capacitor and a circuit for processing a common-mode rejection current are simplified, which facilitates design and optimization of the system structure of the isolation circuit.

In an aspect, a latch circuit includes a first differential input terminal coupled to an isolation circuit for receiving a first differential input signal. The first differential input signal is characterized by a swing voltage of less than 300 mv. The circuit also includes a second differential input terminal coupled to the isolation circuit for receiving a second differential input signal. The circuit also includes a first switch including a first switch input terminal coupled to the first differential input terminal and a first output terminal. The circuit also includes a second switch including a second switch input terminal coupled to the second differential input terminal and a second output terminal. The circuit also includes a first input resistor coupled to the first differential input terminal and the first switch input terminal. The circuit also includes a second input resistor coupled to the second differential input terminal and the second switch input terminal. The circuit also includes a first output resistor coupled to the first output terminal. The circuit also includes a second output resistor coupled to the second output terminal. The circuit also includes a first cascade switch including a third switch input terminal and a first intermediate terminal. The third switch input terminal is coupled to the first output terminal. The first intermediate terminal is coupled to the second output terminal. The circuit also includes a second cascade switch including a fourth switch input terminal and a second intermediate terminal. The fourth switch input terminal is coupled to the second output terminal and the second intermediate terminal is coupled to the first output terminal. The first differential input signal at the first differential input terminal may include a first pulse component and a first non-zero voltage component. The first non-zero voltage component is attributed at least to the first switch and the first input resistor. A first output signal from the first output terminal may include a first voltage component associated with the first switch and a second voltage component associated with the second cascade switch.

In another aspect, an isolation circuit having a latch circuit is provided according to embodiments of the present disclosure. The isolation circuit includes a first input terminal for receiving a first input signal at a first amplitude. The circuit also includes a second input terminal for receiving a second input signal at a second amplitude. The first input signal and the second input signal may be a differential pair. The circuit also includes a first isolation capacitor coupled to the first input terminal for generating a first isolation signal based on the first input signal. The circuit also includes a second isolation capacitor coupled to the second input terminal for generating a second isolation signal based on the second input signal. The circuit also includes a latch circuit coupled to the first isolation capacitor and the second isolation capacitor for receiving the first isolation signal and the second isolation signal and generating a first output signal and a second output signal in response to the first isolation signal and the second isolation signal. The latch circuit may include a first differential input terminal configured to receive the first isolation signal. The first isolation signal may include a first pulse component and a first non-zero voltage component. The first non-zero voltage component is attributed to the latch circuit. The latch circuit also includes a second differential input terminal configured to receive the second isolation signal. The second isolation signal may include a second pulse component and a second non-zero voltage component. The second non-zero voltage component is attributed to the latch circuit. The latch circuit further includes a first switch coupled to the first differential input terminal and a first output terminal. The latch circuit further includes a second switch coupled to the second differential input terminal and a second output terminal. The second switch is cross-coupled with the first switch. The latch circuit also includes a first cascade switch coupled to the first switch and a second cascade switch coupled to the second switch. The first cascade switch may include a third switch input terminal coupled between the first switch and the first output terminal. The second cascade switch may include a fourth switch input terminal coupled between the second switch and the second output terminal. The second cascade switch is cross-coupled with the first cascade switch. A first output signal from the first output terminal may include a first voltage component associated with the first switch and a second voltage component associated with the second cascade switch. A second output signal from the second output terminal may include a third voltage component associated with the second switch and a fourth voltage component associated with the first cascade switch.

It is to be appreciated that embodiments of the present disclosure provide many advantages over conventional techniques. Among other things, latch circuits in accordance with embodiment of the present disclosure enables the change of state in response to input signals with voltage swings lower than 50 mV. Latch and isolation circuits according to embodiments of the present disclosure can operate in high-speed analog circuit systems with low power consumption and high stability and responsiveness.

The present invention achieves these benefits and others in the context of known technology. However, a further understanding of the nature and advantages of the present invention may be realized by reference to the latter portions of the specification and attached drawings.

### BRIEF DESCRIPTION OF THE DRAWINGS

FIG. 1 schematically illustrates a circuit diagram of a latch 100 in an existing technology.

FIG. 2 schematically illustrates a circuit diagram of another latch 200 in the existing technology.

FIG. 3 schematically illustrates a structural block diagram of a latch 300 according to an embodiment of the present disclosure.

FIG. 4 schematically illustrates a circuit diagram of a latch 400 according to an embodiment of the present disclosure.

FIG. 5 schematically illustrates a circuit diagram of a latch 500 according to another embodiment of the present disclosure.

FIG. 6 schematically illustrates a circuit diagram of a latch 600 according to another embodiment of the present disclosure.

FIG. 7 schematically illustrates a circuit diagram of a latch 700 according to another embodiment of the present disclosure.

FIG. 8 schematically illustrates a circuit diagram of an isolation circuit 800 according to an embodiment of the present disclosure.

FIG. 9A schematically illustrates a circuit diagram of an isolation circuit 900 including a latch circuit 920 according to an embodiment of the present disclosure.

FIG. 9B schematically illustrates a timing diagram of the isolation circuit 900 in FIG. 9A during operation periods according to an embodiment of the present disclosure.

### DETAILED DESCRIPTION OF THE INVENTION

The following description is presented to enable one of ordinary skill in the art to make and use the invention and to incorporate it in the context of particular applications. Various modifications, as well as a variety of uses in different applications will be readily apparent to those skilled in the art, and the general principles defined herein may be applied to a wide range of embodiments. Thus, the present invention is not intended to be limited to the embodiments presented, but is to be accorded the widest scope consistent with the principles and novel features disclosed herein.

In the following detailed description, numerous specific details are set forth in order to provide a more thorough understanding of the present invention. However, it will be apparent to one skilled in the art that the present invention may be practiced without necessarily being limited to these specific details. In other instances, well-known structures and devices are shown in block diagram form, rather than in detail, in order to avoid obscuring the present invention.

The reader's attention is directed to all papers and documents which are filed concurrently with this specification and which are open to public inspection with this specification, and the contents of all such papers and documents are incorporated herein by reference. All the features disclosed in this specification, (including any accompanying claims, abstract, and drawings) may be replaced by alternative features serving the same, equivalent or similar purpose, unless expressly stated otherwise. Thus, unless expressly stated otherwise, each feature disclosed is one example only of a generic series of equivalent or similar features.

Furthermore, any element in a claim that does not explicitly state “means for” performing a specified function, or “step for” performing a specific function, is not to be interpreted as a “means” or “step” clause as specified in 35 U.S.C. Section 112, Paragraph 6. In particular, the use of “step of” or “act of” in the Claims herein is not intended to invoke the provisions of 35 U.S.C. 112, Paragraph 6.

Please note, if used, the labels left, right, front, back, top, bottom, forward, reverse, clockwise and counterclockwise have been used for convenience purposes only and are not intended to imply any particular fixed direction. Instead, they are used to reflect relative locations and/or directions between various portions of an object.

As described in the background, a latch including a pair of inverting elements has a flipping amplitude of 0V to a power supply voltage, which can generally meet the application requirements of majority circuits. Conventional latches generally require flipping amplitudes greater than 500 mV and thus are not suited for high-speed analog signal processing with low amplitudes (e.g., lower than 100 mV). The latches with a flipping amplitude of 0V to a power supply voltage in the existing technology are gradually unable to meet the performance requirements of high-performance integrated circuit chips.

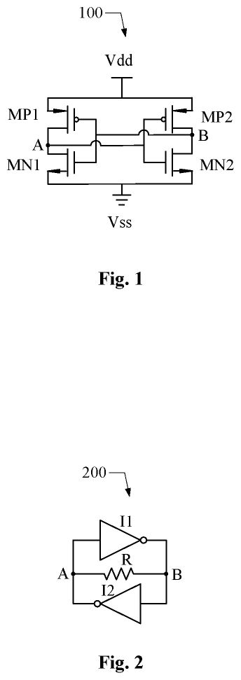

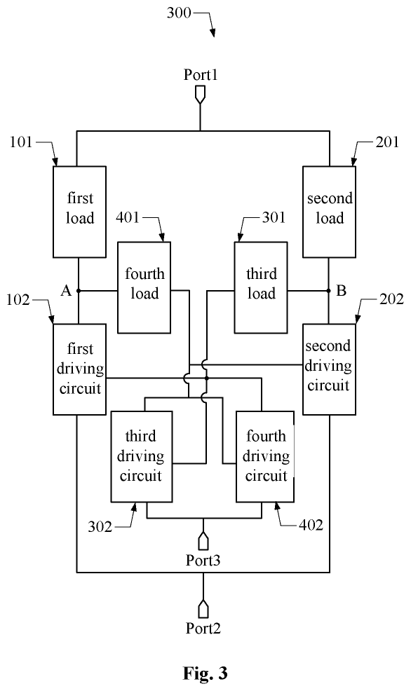

In order to reduce a flipping amplitude of a latch 100 shown in FIG. 1, another latch is provided in the existing technology, and the inventor of the present disclosure analyzes the existing latches. As shown in FIG. 2, the latch 200 may include a first inverter I1, a second inverter I2 and a resistor R, where the first inverter I1 and the second inverter I2 are connected end to end, and the resistor R is connected between an output terminal of the first inverter I1 and an output terminal of the second inverter I2. Each of the first inverter I1 and the second inverter I2 is comprised of a P-type Metal-Oxide-Semiconductor Field-Effect Transistor (MOSFET) and a N-type MOSFET (not shown), which is similar to the two inverters shown in FIG. 1 and will not be described in detail herein.

For simplification, it is assumed that electrical parameters of the first inverter I1 and electrical parameters of the second inverter I2 are the same, and in the first inverter I1, a transconductance of the P-type MOSFET operating in a saturation region is equal to a transconductance of the N-type MOSFET operating in a saturation region.

Further, an operating condition of the latch 200 is gm×R>2, where gm is the transconductance of the P-type MOSFET operating in the saturation region in the first inverter I1 or the transconductance of the N-type MOSFET operating in the saturation region in the second inverter I2, and R is a resistance value of the resistor R. VA and VB are respectively set to be voltage amplitudes of two latching points A and B in the latch 200, VT is a threshold voltage of the P-type MOSFET in the first inverter I1, or a threshold voltage of the N-type MOSFET in the second inverter I2, and Rds is a resistance value of the P-type MOSFET or a resistance value of the N-type MOSFET in a linear region. The P-type MOSFET or the N-type MOSFET enters from the saturation region to the linear region when VA−VB>VT, and the operating condition of the latch 200 becomes gₘ×(Rds//R)≤2, where gₘ≈2/Rds, “Rds//R” represents Rds being connected in parallel with R, that is, (Rds×R)/(Rds+R). Therefore, V_{T} is the flipping amplitude of the latch 200.

In the existing integrated circuit processes, VT is generally 0.7V or 0.3V but not a constant. As a result, the flipping amplitude of the latch 200 varies with different chips. In general, the circuit application requirements of the latch 200 can only be met when VT is maintained stably around 500 mV.

The inventor further analyzes that, the smaller a flipping amplitude, the smaller a flipping energy required for a latch to enter a steady state, under a premise of a small parasitic capacitance. For example, when the latch is applied to an isolation circuit, energy of the isolation circuit is transmitted by its internal main isolating capacitor. The larger the flip energy consumed when the latch enters the steady state, the larger a capacitance of the main isolating capacitor, the larger an area of the chip carrying the isolation circuit, the higher the consumption cost, and the more complicated a circuit driving the main isolating capacitor and a circuit processing a common-mode rejection current. In addition, the isolated signal in the isolation circuit is generally attenuated at a predetermined ratio, for example, at a ratio of 30:1, and when the flipping amplitude of the latch is too large, there is a large difference between the attenuated flipping amplitude and the original flipping amplitude, which is not beneficial for system design. If the predetermined ratio of attenuation is reduced, the system design will become more complicated and the chip area will be increased. Therefore, an optimum approach for constructing an isolation circuit seems to be reducing a flipping amplitude of a latch.

Based on the above analysis and development trend of current integrated circuits, the flipping amplitudes of the aforementioned latches in the existing technology are too large to meet performance requirements of high-performance integrated circuits (e.g. isolation circuits).

In view of the above-mentioned technical problems, a latch having a flipping amplitude of any value between several millivolts and several volts is provided according to embodiments of the present disclosure, which can be achieved at any temperature and on any production line based on the process level in the existing technologies, so as to meet the performance requirements of high-performance integrated circuits (such as isolation circuits).

The foregoing objects, features and advantages of the present invention will become more apparent from the following detailed description of specific embodiments of the invention taken in conjunction with the accompanying drawings.

FIG. 3 schematically illustrates a structural block diagram of a latch 300 according to an embodiment of the present disclosure.

Referring to FIG. 3, the latch 300 may include a first-level substructure (now shown) and at least one second-level substructure (now shown), where the at least one second-level substructure has a number of k, and k is a positive integer greater than or equal to 1. For simplification, the latching 300 including a second-level substructure is shown in FIG. 3.

Specifically, the first-level substructure may include a first load 101, a second load 201, a first driving circuit 102 and a second driving circuit 202. Each of the at least one second-level substructure may include a third load 301, a fourth load 401, a third driving circuit 302 and a fourth driving circuit 402.

A first terminal of the first load 101 may be coupled with a first port Port1, a first terminal of the second load 201 may be coupled with the first port Port1, a control terminal A of the first driving circuit 102 may be coupled with a second terminal of the first load 101, a second terminal of the first driving circuit 102 may be coupled with a second port Port2, a control terminal B of the second driving circuit 202 may be coupled with a second terminal of the second load 201, and a second terminal of the second driving circuit 202 may be coupled with the second port Port2. The control terminal A of the first driving circuit 102 and the control terminal B of the second driving circuit 202 may serve as two latching points of the latch 300.

In a first second-level substructure, a first terminal of the third load 301 may be coupled with a second terminal of the second load 201, and a second terminal of the third load 301 may be coupled with a control terminal of the third driving circuit 302, a first terminal of the first driving circuit 102 and a first terminal of the fourth driving circuit 402, a first terminal of the fourth load 401 may be coupled with the second terminal of the first load 101, a second terminal of the fourth load 401 may be coupled with a control terminal of the fourth driving circuit 402, a first terminal of the second driving circuit 202 and a first terminal of the third driving circuit 302, and a second terminal of the third driving circuit 302 and a second terminal of the fourth driving circuit 402 may be coupled with a first reference port Port3.

In a second second-level substructure (not shown), a first terminal of the third load (not shown) is coupled with the second terminal of the fourth load 401 of the first second-level substructure, a second terminal of the third load may be coupled with a control terminal of the third driving circuit (not shown), a first terminal of the third driving circuit 302 of the first second-level substructure, and a first terminal of the fourth driving circuit (not shown), a first terminal of the fourth load is coupled with the second terminal of the third load 301 of the first second-level substructure, a second terminal of the fourth load is coupled with a control terminal of the fourth driving circuit, the first terminal of the fourth driving circuit 402 of the first second-level substructure and a first terminal of the third driving circuit, and a second of the third driving circuit and a second terminal of the fourth driving circuit may be coupled with a second reference port (not shown). A circuit connection relationship of a third second-level substructure and circuit connection relationships of even more second-level substructures may be derived by analogy, which will not be described in detail herein.

From above, it can be concluded that, in an i-th second-level substructure, wherein i is a positive integer greater than 1 and less than or equal to k, a first terminal of the third load may be coupled with a second terminal of the fourth load of an (i−1)-th second-level substructure, and a second terminal of the third load may be coupled with a control terminal of the third driving circuit, a first terminal of the third driving circuit of the (i−1)-th second-level substructure and a first terminal of the fourth driving circuit, a first terminal of the fourth load may be coupled with a second terminal of the third load of the (i−1)-th second-level substructure, a second terminal of the fourth load may be coupled with a control terminal of the fourth driving circuit, a first terminal of the fourth driving circuit of the (i−1)-th second-level substructure and a first terminal of the third driving circuit, and a second terminal of the third driving circuit and a second terminal of the fourth driving circuit may be coupled with an i-th reference port (not shown).

In some embodiment, the first load 101, the second load 201, the third load 301 and the fourth load 401 may be elements or devices with two terminals; and the first driving circuit 102, the second driving circuit 202, the third driving circuit 302 and the four driving circuit 402 may be elements or devices with three terminals. That is, the driving capabilities of the first driving circuit 102, the second driving circuit 202, the third driving circuit 302, and the fourth driving circuit 402 may be controlled by input parameters of their respective control terminals.

It should be noted that, the present disclosure imposes no limitation on the specific forms of the first port Port1, the second port Port2 and the i-th reference port, which may be any appropriate ports. In some embodiment, the first port Port1, the second port Port2 and the i-th reference port may be selected from a group of power supply ports, ground terminals, input/output ports of other functional circuits and other ports with potential values other than 0V.

In some embodiment, the first load 101, the second load 201, the third load 301 and the fourth load 401 may be any devices with current suppression capability. For example, one or more of the first load 101, the second load 201, the third load 301 and the fourth load 401 may be resistors, but are not limited thereto. For example, the first load 101, the second load 201, the third load 301 and the fourth load 401 may also be any of resistance and capacitances, or a combination thereof.

In some embodiment, each of the first driving circuit 102, the second driving circuit 202, the third driving circuit 302 and the fourth driving circuit 402 may be any device with current driving capability, such as an appropriate transistor or inverter, where the transistor may include a unipolar transistor also referred to as a field effect transistor, e.g. an N-type MOSFET or a P-type MOSFET), or a bipolar transistor referred to as a Bipolar Junction Transistor (BJT). The currents output by the first driving circuit 102, the second driving circuit 202, the third driving circuit 302 and the fourth driving circuit 402 may be determined based on a signal (for example, a voltage or current signal) applied to each terminal of the four driving circuits.

For simplification, in an embodiment of the present disclosure, the first load 101, the second load 201, the third load 301 and the fourth load 401 are resistors, and the first driving circuit 102, the second driving circuit 202, the third driving circuit 302 and the fourth driving circuit 402 are transistors.

Specifically, the first driving circuit 102 may include a first transistor (not shown), a control terminal of the first transistor may serve as the control terminal of the first driving circuit 102, a first terminal of the first transistor may serve as the first terminal of the first driving circuit 102, and a second terminal of the first transistor may serve as a second terminal of the first driving circuit 102. The second driving circuit 202 may include a second transistor (not shown), a control terminal of the second transistor may serve as the control terminal of the second driving circuit 202, a first terminal of the second transistor serves as the first terminal of the second driving circuit 202, and a second terminal of the second transistor may serve as the second terminal of the second driving circuit 202.

Specifically, the third driving circuit 302 may include a third transistor (not shown), a control terminal of the third transistor may serve as the control terminal of the third driving circuit 302, a first terminal of the third transistor may serve as the first terminal of the third driving circuit 302, and a second terminal of the third transistor may serve as a second terminal of the third driving circuit 302. The fourth driving circuit 402 may include a fourth transistor (not shown), a control terminal of the fourth transistor may serve as the control terminal of the fourth driving circuit 402, a first terminal of the fourth transistor may serve as the first terminal of the fourth driving circuit 402, and a second terminal of the four transistor may serve as the second terminal of the fourth driving circuit 402.

It should be understood by those skilled in the art that, the transistor is a device having three terminals. For a unipolar transistor, a control terminal of the unipolar transistor may be generally a gate, and a first terminal and a second terminal of the unipolar transistor may be a drain and a source respectively, or a source and a drain respectively. For a bipolar transistor, a control terminal of the bipolar transistor may be generally a base, and a first terminal and a second terminal of the bipolar transistor may be a collector and an emitter respectively, or an emitter and a collector respectively.

In some embodiment, the electrical parameters of the first load 101 and the second load 201 may be the same or different, the electrical parameters of the first driving circuit 102 and the second driving circuit 202 may be the same or different, the electrical parameters of the third load 301 and the fourth load 401 may be the same or different, and the electrical parameters of the third driving circuit 302 and the fourth driving circuit 402 may be the same or different.

Specifically, the electrical parameters of the first load 101 and the second load 201 are the same, the electrical parameters of the first driving circuit 102 and the second driving circuit 202 are the same, the electrical parameters of the third load 301 and the fourth load 401 are the same, and the electrical parameters of the third driving circuit 302 and the fourth driving circuit 402 are also the same. That is, preferably, the circuit structure and the electrical parameters of the latch 300 are symmetrical.

When the circuit structure and/or electrical parameters of the latch 300 are not completely symmetrical, there will be a gain factor between logic levels of the control terminal A of the first driving circuit 102 and the control terminal B of the second driving circuit 202 (i.e. the two latching points of the latch 300), where the gain factor depends on the electrical parameters (e.g. impedance values) of the first load 101, the second load 201, the third load 301 and the fourth load 401 and the electrical parameters (e.g. magnitude of output currents) of the first driving circuit 102, the second driving circuit 202, the third driving circuit 302, and the fourth driving circuit 402.

Based on the above circuit structure, when the latch 300 includes the first-level substructure and a second-level substructure, a flipping amplitude of the latch 300 may be determined based on the electrical parameters (e.g. impedance values) of the first load 101, the second load 201, the third load 301 and the fourth load 401 and the electrical parameters (e.g. magnitude of output currents) of the first driving circuit 102, the second driving circuit 202, the third driving circuit 302, and the fourth driving circuit 402. For simplification, in some embodiment, an impedance value of the first load 101 and an impedance value of the second load 201 may be equal and may be R1, a resistance value of the third load 301 and a resistance value of the fourth load 401 may be equal and may be R2, an output current of the first driving circuit 102 and an output current of the second driving circuit 202 may be equal and may be I1, and an output current of the third driving circuit 302 and an output current of the fourth driving circuit 402 may be equal and may be I2.

The flipping amplitude of the latch 300 according to embodiments of the present disclosure may be determined according to the impedance value R1 and magnitude of the current I2. Since R1 and I2 may have a wide design range, the flipping amplitude can be any value from several millivolts to several volts, and can be achieved at any temperature and on any production line based on the process level in the existing technology. With the development trend of integrated circuits, the flipping amplitude of the latch 300 can meet the performance requirements of high-performance integrated circuits such as an isolation circuit.

It should be noted that, when the latch 300 includes a first-level substructure and a plurality of second-level substructures, the method for calculating the flipping amplitude of the latch 300 may be appropriately adjusted, but the flipping amplitude can still be flexibly designed based on the wide design ranges of output currents of corresponding driving circuits.

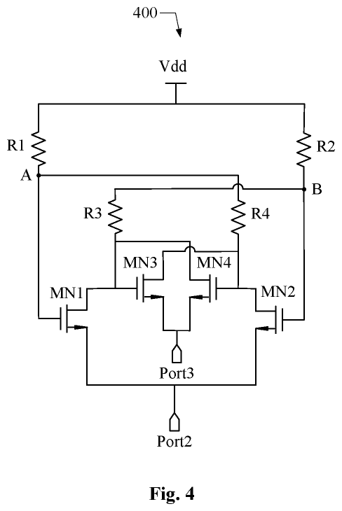

FIG. 4 schematically illustrates a circuit diagram of a latch 400 according to an embodiment of the present disclosure.

The circuit structure and operating principle of the latch 400 shown in FIG. 4 is basically similar to that of the latch 300 shown in FIG. 3. A main difference lies in that, in the latch 400, a first load, a second load, a third load and a fourth load may be resistors and are respectively labeled as R1, R2, R3 and R4. A first transistor, a second transistor, a third transistor and a fourth transistor may be N-type MOSFETs and are respectively labeled with MN1, MN2, MN3 and MN4.

Specifically, a first port (not shown) may be a power supply port (not shown), and the power supply port is configured to be input with a power supply voltage Vdd.

A gate A of the first transistor MN1 may be connected with a second terminal of the first load R1, a drain of the first transistor MN1 may be connected with a second terminal of the third load R3 in the first second-level substructure, and a source of the first transistor MN1 may be connected with a second port Port2. A gate B of the second transistor MN2 may be connected with the second terminal of the second load R2, a drain of the second transistor MN2 may be connected with a second terminal of the fourth load R4 in the first second-level substructure, and a source of the second transistor MN2 may be connected with the second port Port2. The second port Port2 may be any appropriate port, for example, an input/output port of other functional circuits, or a port with an appropriate potential.

In the first second-level substructure, a gate of the third transistor MN3 may be connected with a drain of the first transistor MN1, a second end of the third load R3 and a drain of the fourth transistor MN4, and a source of the third transistor MN3 may be connected with a first reference port Port3. A gate of the fourth transistor MN4 may be connected with a drain of the second transistor MN2, a second terminal of the fourth load R4 and a drain of the third transistor, a source of the fourth transistor MN4 may be connected with the first reference port Port3. The first reference port Port3 may be any appropriate port, for example, an input/output port of other functional circuits, or a port with an appropriate potential.

The specific circuit structure and more information about the latch 400 including a plurality of second-level substructures may be derived by reference to the above description on the latch 300 shown in FIG. 3, which will not be described in detail herein.

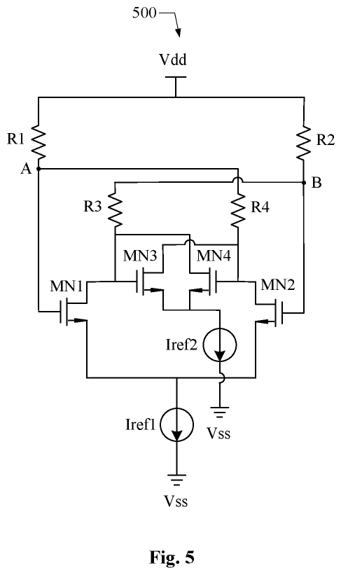

FIG. 5 schematically illustrates a circuit diagram of a latch 500 according to another embodiment of the present disclosure.

The circuit structure and operating principle of the latch 500 shown in FIG. 5 is basically the same as that of the latch 400 shown in FIG. 4. A main difference lies in that, in the latch 500, the second port (not shown) may be coupled with an output terminal of a first current source Iref1, and an input terminal of the first current source Iref1 may be coupled with a ground terminal Vss. Further, the first current source Iref1 can provide a pull-down current (not shown) to the first transistor MN1 and the second transistor MN2, and when the second port is coupled with the first current source Iref1, the aforementioned I1 is the output current of the first current source Iref1.

Similarly, the first reference port (not shown) may be coupled with an output terminal of a second current source Iref2, and an input terminal of the second current source Iref2 may also be coupled with the ground terminal Vss. Further, the second current source Iref2 may provide a pull-down current (not shown) for the third transistor MN3 and the fourth transistor MN4 in the first second-level substructure, and when the first reference port is coupled with the second current source Iref2, the aforementioned I2 is the output current of the second current source Iref2.

It should be noted that, the present disclosure imposes no limitation on the circuit structures of the first current source Iref1 and the second current source Iref2, which may be any form of reference current source as long as the reference current source can provide a pull-down current.

More information about the latch 500 can be derived by reference to the above description on the latch 400 shown in FIG. 4, which will not be described in detail herein.

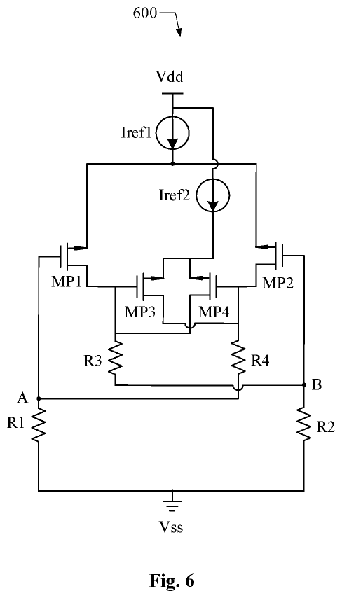

FIG. 6 schematically illustrates a circuit diagram of a latch 600 according to another embodiment of the present disclosure.

The circuit structure and operating principle of the latch 600 shown in FIG. 6 is basically the same as that of the latch 500 shown in FIG. 5. A main difference lies in that, in the latch 600, the first transistor, the second transistor, the third transistor and the fourth transistor may be P-type MOSFETs and are labeled as MP1, MP2, MP3 and MP4, respectively.

Specifically, the first port (not shown) may be directly or indirectly coupled with a reference ground Vss. In FIG. 6, the first port is directly coupled with the reference ground Vss. The second port (not shown) may be coupled with an output terminal of the first current source Iref1, an input terminal of the first current source Iref1 may be coupled with a power supply port (not shown), and the power supply port is configured to be input with a power supply voltage Vdd. The first reference port (not shown) may be coupled with an output terminal of the second current source Iref2, and an input terminal of the second current source Iref2 may be coupled with the power supply port. In the first second-level substructure, the first terminal of the third load R3 and the first terminal of the fourth load R4 may be indirectly coupled with the reference ground Vss.

A gate A of the first transistor MP1 may be connected with a second terminal of the first load R1, a drain of the first transistor MP1 may be connected with a second terminal of the third load R3 in the first second-level substructure, and a source of the first transistor MP1 may be connected with the second port. A gate B of the second transistor MP2 may be connected with a second terminal of the second load R2, a drain of the second transistor MP2 may be connected with a second terminal of the fourth load R4 in the first second-level substructure, and a source of the second transistor MP2 may be connected with the second port.

In the first second-level substructure, a gate of the third transistor MP3 may be connected with the drain of the first transistor MP1, a second terminal of the third load R3, and a drain of the fourth transistor MP4, a source of the third transistor MP3 may be connected with the first reference port, a gate of the fourth transistor MP4 may be connected with a drain of the second transistor MP2, a second terminal of the fourth load R4, and the drain of the third transistor, and a source of the fourth transistor MP4 may be connected with the first reference port.

The specific circuit connection structure and more information on the latch 600 including a plurality of second-level substructures may be derived by reference to the above description on the latch 500 shown in FIG. 5, which will not be described in detail herein.

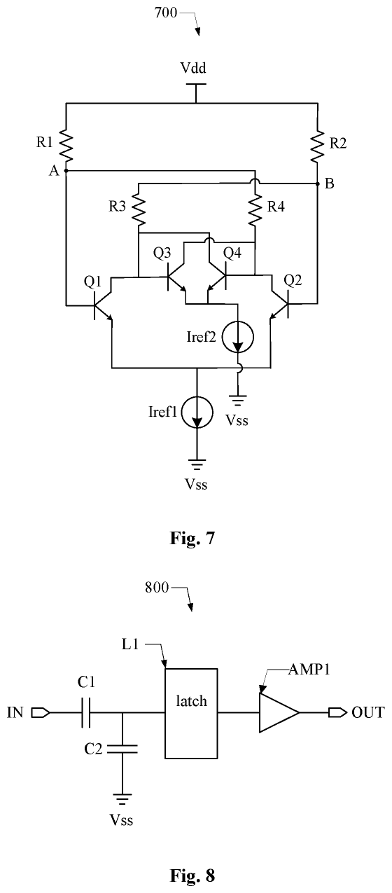

FIG. 7 schematically illustrates a circuit diagram of a latch 700 according to another embodiment of the present disclosure.

The circuit structure and operating principle of the latch 700 shown in FIG. 7 is basically the same as that of the latch 500 shown in FIG. 5. A main difference lies in that, the first transistor, the second transistor, the third transistor and the fourth transistor in the latch 700 may be bipolar transistors and denoted by Q1, Q2, Q3 and Q4 respectively.

Specifically, the first port (not shown) may be a power supply port (not shown), and the power supply port may be configured to be input with a power supply voltage Vdd.

A base A of the first transistor Q1 may be connected with a second terminal of the first load R1, a collector of the first transistor Q1 may be connected with a second terminal of the third load R3 in the first second-level substructure, and an emitter of the first transistor Q1 may be connected with the second port (not shown). In the embodiment shown in FIG. 7, the emitter of the first transistor Q1 is coupled with an output terminal of a first current source Iref1. A base B of the second transistor Q2 may be connected with a second terminal of the second load R2, a collector of the second transistor Q2 may be connected with a second terminal of the fourth load R4 in the first second-level substructure, and an emitter of the second transistor Q2 may be connected with the second port.

In the first second-level substructure, a base of the third transistor Q3 may be connected with a collector of the first transistor Q1, a second terminal of the third load R3 and a collector of the fourth transistor Q4. An emitter of the third transistor Q3 may be connected with a first reference port (not shown). In the embodiment shown in FIG. 7, the emitter of the third transistor Q3 may be connected with an output terminal of a second current source Iref2. A base of the fourth transistor Q4 may be connected with a collector of the second transistor Q2, a second terminal of the fourth load R4 and a collector of the third transistor, and an emitter of the fourth transistor Q4 may be connected with the first reference port.

The specific circuit structure and more information about the latch 700 including a plurality of second-level substructures may be derived by reference to the above description on the latch 400 shown in FIG. 4 and the latch 500 shown in FIG. 5, which will not be described in detail herein.

FIG. 8 schematically illustrates a circuit diagram of an isolation circuit 800 according to an embodiment of the present disclosure.

As shown in FIG. 8, the isolation circuit 800 may include a latch according to any of the embodiments shown in FIG. 3 to FIG. 7. Since the flipping amplitude of the latch in the present disclosure may be any value from several millivolts to several volts, the flipping energy required to bring the latch into a steady state may be small, and a capacitance of a main isolating capacitor C1 applied to transmit energy in the isolation circuit 800 is small. Accordingly, a chip area of the isolation circuit 800 and the cost can be both reduced. In addition, a circuit (not shown) for driving the main isolating capacitor C1 and a circuit (not shown) for processing a common-mode rejection current are simplified, which can facilitate design and optimization of the system structure of the isolation circuit 800.

As a non-limiting example, the isolation circuit 800 may include a main isolating capacitor C1, a voltage dividing capacitor C2, a latch L1 according to any of the embodiments shown in FIG. 3 to FIG. 7), and an amplifier AMP1.

A first terminal of the main isolating capacitor C1 may be coupled with an input terminal IN of the isolation circuit 800, and a second terminal of the main isolating capacitor C1 may be coupled with a first terminal of the voltage dividing capacitor C2 and a control terminal A of the first driving circuit 102 shown in FIG. 3. A second terminal of the voltage dividing capacitor C2 may be coupled with a ground terminal Vss, the control terminal B of the second driving circuit 202 shown in FIG. 3 may be coupled with an input terminal of the amplifier AMP1, and an output terminal of the amplifier AMP1 may be coupled with an output terminal OUT of the isolation circuit 800.

It should be noted that, in order to improve an anti-interference performance of the circuit, the isolation circuit 800 may also have a differential structure (not shown), that is, the isolation circuit 800 may be input with a differential signal. Correspondingly, the isolation circuit 800 may include two main isolating capacitors C1, two voltage dividing capacitors C2, and two latches L1, which will not be described in detail herein.

It should also be noted that, the terminology of “coupled” in the embodiments of the present disclosure refers to a direct connection or an indirect connection through other elements or devices.

The latch circuits disclosed in the present application can be used in various applications, such as automotive applications, communication applications, industrial applications, computer applications, and/or consumer or appliance applications. The latch circuit can be implemented in a substrate, such as a semiconductor wafer, a printed circuit board (PCB), and/or system-on-chip. As an example, the use of the latch circuits in an isolation circuit is described below.

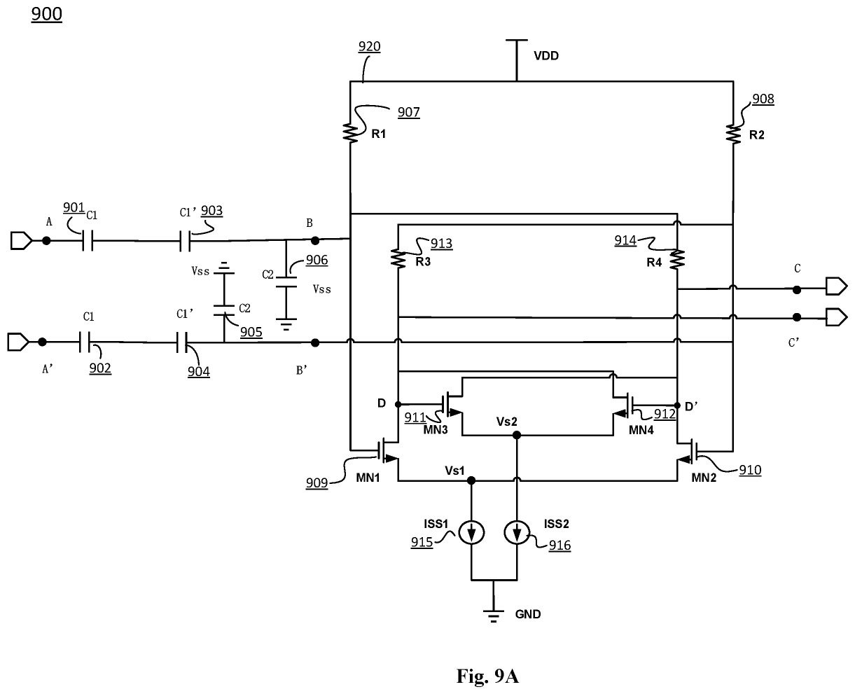

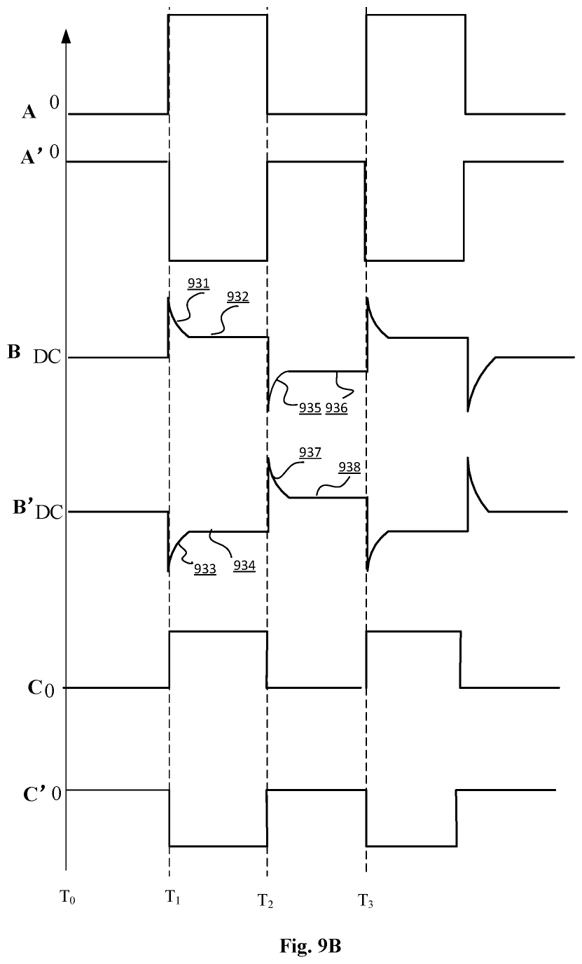

FIG. 9A shows a schematic diagram of an isolation circuit 900 according to embodiments of the present invention, which may be configured between a transmitter and a receiver (not shown). This diagram is merely an example, which should not unduly limit the scope of the claims. One of ordinary skill in the art would recognize many variations, alternatives, and modifications. Isolation circuit 900 includes a first input terminal (e.g., node A), a second input terminal (e.g., node A′), a first isolation capacitor 901, a second isolation capacitor 902, and a latch circuit 920. In some cases, isolation circuit may further includes a third isolation capacitor 903, a fourth isolation capacitor 904. The first input terminal is configured to receive a first input signal at a first amplitude. The second input terminal is configured to receive a second input signal at a second amplitude. In some cases, the first input signal and the second input signal may be a differential pair of signals. For example, the first amplitude and the second amplitude may be greater than or equal to 1.8V.

The first input terminal is coupled to first isolation capacitor 901. First isolation capacitor 901 is configured to generate a first isolation signal based on the first input signal. It is to be appreciated that the first isolation signal may be characterized by an amplitude lower than the first amplitude due to the voltage-dividing capability of first isolation capacitor 901. The second input terminal is coupled to second isolation capacitor 902. Second isolation capacitor 902 is configured to generate a second isolation signal based on the second input signal. Similarly, the second isolation signal may be characterized by an amplitude lower than the second amplitude due to the voltage-dividing capability of second isolation capacitor 902. For example, the first isolation signal and the second isolation signal may be characterized by a swing voltage of less than 300 mV. First isolation capacitor 901 and second isolation capacitor 902 may be coupled to a latch circuit 920 and output the first isolation signal and the second isolation signal to latch circuit 920. In some cases, third isolation capacitor 903 and fourth isolation capacitor 904 may be coupled to latch circuit 920 and output isolation signals to latch circuit 920.

According to some embodiments, latch circuit 920 comprises a first differential input terminal (e.g., node B), a second differential input terminal (e.g., node B′), a first switch 909, a second switch 910, a first input resistor 907, a second input resistor 908, a first output resistor 913, a second output resistor 914, a first output terminal (e.g., node C′), a second output terminal (e.g., node C), a first cascade switch 911, and a second cascade switch 912. For example, switch 909 and switch 911 are configured in parallel; switch 910 and switch 910 are configured in parallel. For example, the first differential input terminal is coupled to first isolation capacitor 901 and receives a first differential input signal (e.g., the first isolation signal) at node B. The second differential input terminal is coupled to second isolation capacitor 902 and receives a second differential input signal (e.g., the second isolation signal) at node B′. Due to the proximity among the electronic components, parasitic capacitance may exist between the parts of the electronic components or isolation circuit. In some cases, a first parasitic capacitance 906 may exist at the first differential input terminal of latch circuit 920 and a second parasitic capacitance 905 may exist at the second differential input terminal of latch circuit 920.

In some embodiments, first switch 909 comprises a first switch input terminal and a first output terminal. The first output terminal of first switch 909 may also be configured as a first output terminal of the latch circuit such that a first output terminal is outputted from the first output terminal (e.g., node C′). First switch 909 is configured to provide amplification to the first differential input signal received at the first switch input terminal when enabled such that a first output signal from the first output terminal may be associated with first switch 909. As an example, the term “switch” refers to semiconductor transistor that include MOSFET and BJT devices, which can operate in “on” and “off” states and/or provide amplification to electrical signals. For example, first switch 909 comprises a MOSFET transistor (e.g., P-Channel MOSFET, N-Channel MOSFET, etc.). Second switch 910 comprises a second switch input terminal and a second output terminal. The second output terminal of second switch 910 may also be configured as a second output terminal of the latch circuit such that a second output terminal is outputted from the second output terminal (e.g., node C). Second switch 910 is configured to provide amplification to the second differential input signal received at the second switch input terminal when enabled such that a second output signal from the second output terminal may be associated with second switch 910. For example, second switch 910 comprises a MOSFET transistor (e.g., P-Channel MOSFET, N-Channel MOSFET, etc.). Second switch 910 is cross-coupled with first switch 909, for example, the first switch input terminal is coupled to the second output terminal through second output resistor 914, and the second switch input terminal is coupled to the first switch output terminal through first output resistor 915. For example, the first output terminal and the second output terminal of latch circuit 920 may be coupled to and output the first output signal and the second output signal to an amplifier (e.g., AMP1 in FIG. 8, not shown in FIG. 9A) of an isolation circuit for further amplification.

According to some embodiments, first input resistor 907 is coupled to the first differential input terminal and the first switch input terminal of first switch 909. Second input resistor 908 is coupled to the second differential input terminal and the second switch input terminal of second switch 910. A supply voltage V_{DD} is coupled to both first input resistor 907 and second input resistor 908 to provide power to latch circuit 920. First output resistor 913 is coupled to the first output terminal (e.g., node C′). Second output resistor 914 is coupled to the second output terminal (e.g., node C).

According to some embodiments, first cascade switch 911 comprises a third switch input terminal and a first intermediate terminal. For example, first cascade switch 911 comprises a MOSFET transistor (e.g., P-Channel MOSFET, N-Channel MOSFET, etc.). The third input terminal of first cascade switch 911 is coupled to the first output terminal of latch circuit 920. The first intermediate terminal is coupled to the second output terminal of latch circuit 920 such that the second output signal from the second output terminal is associated with first cascade switch 911. First cascade switch 911 is configured to receive a first intermediate signal at the third input terminal. Second cascade switch 912 comprises a fourth switch input terminal and a second intermediate terminal. For example, second cascade switch 912 comprises a MOSFET transistor (e.g., P-Channel MOSFET, N-Channel MOSFET, etc.). The fourth switch input terminal of second cascade switch 912 is coupled to the second output terminal of latch circuit 920 and the second intermediate terminal of second cascade switch 912 is coupled to the first output terminal of latch circuit 920 such that the first output signal from the first output terminal is associated with the second cascade switch 912. Second cascade switch 912 is configured to receive a second intermediate signal at the fourth switch input terminal. First cascade switch 911 is cross-coupled with the second cascade switch 912, that is, the third switch input terminal of first cascade switch 911 is coupled to the second intermediate terminal of second cascade switch 912, and the fourth switch input terminal of second cascade switch 912 is coupled to the first intermediate terminal of first cascade switch 911.

In some cases, latch circuit 920 further comprises a first current source 915 and a second current source 916. First current source 915 is coupled to first switch 909 and second switch 910. First current source 915 is configured to provide a first pull-down current to first switch 909 and second switch 910. Second current source 916 is coupled to first cascade switch 911 and second cascade switch 912. Second current source 916 is configured to provide a second pull-down current to first cascade switch 911 and second cascade switch 912. Both first current source 915 and second current source 916 are coupled to circuit ground GND.

FIG. 9A illustrates a schematic diagram of the isolation circuit where first switch 909, second switch 910, first cascade switch 911, and second cascade switch comprise a N-MOSFET, respectively. For example, first switch 909 comprises a first transistor MN1, which includes a first transistor gate, a first transistor drain, and a first transistor source. The first transistor gate is configured as the first switch input terminal of first switch 909. The first transistor drain is configured as the first output terminal of first switch 909. The first transistor source is coupled to the first current source 915, which provides the first pull-down current to the first transistor MN1.

Second switch 910 comprises a second transistor MN2, which includes a second transistor gate, a second transistor drain, and a second transistor source. The second transistor gate is configured as the second switch input terminal of second switch 910. The second transistor drain is configured as the second output terminal of second switch 910. The second transistor source is coupled to the first current source 915, which provides the first pull-down current to the second transistor MN2. First transistor MN1 is cross-coupled with second transistor MN2, that is, the first transistor gate is coupled to the second transistor drain and the second transistor gate is coupled to the first transistor drain. First input resistor 907 is coupled between the supply voltage V_{DD} and the first transistor gate. Second input resistor 908 is coupled between the supply voltage V_{DD} and the second transistor gate.

First cascade switch 911 comprises a third transistor MN3, which includes a third transistor gate, a third transistor drain, and a third transistor source. The third transistor gate is configured as the third switch input terminal of first cascade switch 911. The third transistor drain is configured as the first intermediate terminal of first cascade switch 911. The third transistor source is coupled to the second current source 916, which provides the second pull-down current to the third transistor MN3. Second cascade switch 912 comprises a fourth transistor MN4, which includes a fourth transistor gate, a fourth transistor drain, and a fourth transistor source. The fourth transistor gate is configured as the fourth switch input terminal of second cascade switch 912. The fourth transistor drain is configured as the second intermediate terminal of second cascade switch 912. The third transistor source is coupled to the second current source 916, which provides the second pull-down current to the fourth transistor MN4.

FIG. 9B illustrates a circuit timing diagram for explaining an operation of latch circuit 920 in FIG. 9A according to some embodiments. Latch circuit 920 in FIG. 9A operates as follows. A first input signal characterized by a first amplitude is received at the first input terminal (e.g., node A) of isolation circuit 900. A second input signal characterized by a second amplitude is received at the second first input terminal (e.g., node A′) of isolation circuit 900. It is to be appreciated that the first input signal and the second input signal may form a differential pair of signals for benefits such as EM (Electromagnetic) interference resistance, electronic crosstalk minimization, common-mode interference immunity, etc. For example, the first amplitude of the first input signal and the second amplitude of the second input signal may be greater than 500 mV. First isolation capacitor 903 receives the first input signal at a first end and output a first isolation signal at a second end. Similarly, second isolation capacitor 902 receives the second input signal at a first end and output a second isolation signal at a second end. Due to the voltage-dividing ability of capacitors, the first isolation signal may be characterized by an amplitude lower than the first amplitude of the first input signal, and the second isolation signal may be characterized by an amplitude lower than the second amplitude of the second input signal. For example, both the first isolation signal and the second isolation signal may be characterized by a swing voltage of less than 300 mV. In some cases, the first isolation signal and the second isolation signal may be characterized by a swing voltage of less than 50 mV. The first isolation signal is then received at the first differential input terminal (e.g., node B) of latch circuit 920. The second isolation signal is received at the second differential input terminal (e.g., node B′) of latch circuit 920.

Latch circuit has two stable states and is used to store information. The change of output signals of latch circuit based on the change of the input signals may be referred to as “flipping,” that is, the latch circuit changes from one stable state to another. Latch circuit 920 is controlled by the input signals (e.g., the first differential input signal at node B and the second differential input signal at node B′) of the latch circuit. In this case, the state of latch circuit 920 is controlled by the first isolation signal received at node B and the second isolation signal received at node B′. The change of state of the latch circuit is triggered upon the edge of the input signals and is associated with the amplitude of the input signals. The minimum amplitude of the input signal that allows the latch circuit to change from one stable state to another may be referred to as flipping amplitude ΔV. For conventional latch circuits, the flipping amplitudes are usually above 500 mV. In contrast, latch circuits disclosed in the present application allows for lower flipping amplitudes, and therefore is better suited for the high-speed analog circuit applications.

As shown in FIG. 9B, during a first operating period T₁ to T₂, latch circuit 920 receives the first differential input signal at node B (i.e., the first differential input terminal) and the second differential input signal at node B′ (i.e., the second differential input terminal). Latch circuit 920 is configured to hold the input signals at each edge (e.g., falling edge or rising edge) of the first and second differential input signals, respectively. As such, the first differential input signal of latch circuit 920 comprises a first pulse component 931 and a first non-zero voltage component 932. The first non-zero voltage component 932 is attributed at least to the first transistor MN1 and first input resistor 907. The second differential input signal of latch circuit 920 comprises a second pulse component 933 and a second non-zero voltage component 934. The second non-zero voltage component 934 is attributed at least to the second transistor MN2 and second input resistor 908.

First transistor MN1 and second transistor MN2 determine the output signal of latch circuit 920 based on the input signals of latch circuit 920. When an amplitude of the first pulse component is greater than the flipping amplitude of latch circuit 920, latch circuit 920 changes from one stable state to another and the output signals of latch circuit changes accordingly (e.g., from level high to level low, or from level low to level high, etc.). For conventional analog latch circuits, the non-zero component included in the input signal are usually characterized by much higher amplitudes (e.g., greater than 500 mV) and thus are not well suited for high-speed isolation circuit applications. In contrast, latch circuits disclosed in the present application comprises both the pulse component that can trigger the signal transition and the non-zero voltage component that allows for high-speed signal processing with lower power consumption. The first non-zero voltage component 932 may be attributed at least to first transistor MN1 and first input resistor 907. For example, the first non-zero voltage component 932 may be lower than 50 mV, which makes lower flipping amplitude for latch circuit 920 possible. First input resistor 907 is coupled between the supply voltage V_{DD} and first transistor MN1. When first transistor MN1 is turned on, there is a voltage drop across first input resistor 907 and first input resistor 907 thus provides a first DC component to the first differential input signal at node B.

Similarly, the second differential input signal of latch circuit 920 comprises a second pulse component 933 and a second non-zero voltage component 934. When an amplitude of the second pulse component is greater than the flipping amplitude of latch circuit 920, latch circuit 920 changes from one stable state to another and the output signals of latch circuit changes accordingly. The second non-voltage component 934 may be attributed at least to second transistor MN2 and second input resistor 908. For example, the second non-zero voltage component 934 may be lower than 50 mV, which makes lower flipping amplitude for latch circuit 920 possible. Second input resistor 908 is coupled between the supply voltage V_{DD} and second transistor MN2. When second transistor MN2 is turned on, there is a voltage drop across second input resistor 908 and second input resistor 908 thus provides a second DC component to the second differential input signal at node B′. It is desirable that first input resistor 907 and second input resistor 908 are of matched impedance to reduce common-mode interference.

First transistor MN1 is characterized by a first drive strength. When first transistor MN1 is enabled (or switched “on”) in response to the first differential input signal (e.g., the first isolation signal from the isolation circuit) received at the first transistor gate, the first drive strength is associated with the first differential input signal. Second transistor MN2 is characterized by a second drive strength. When second transistor MN2 is enabled in response to the second differential input signal (e.g., the second isolation signal from the isolation circuit) received at the second transistor gate, the second drive strength is associated with the second differential input signal. First current source 915 is coupled to first transistor MN1 and second transistor MN2, both of which produced an inverted output with respect to the input. First current source 915 is configured to provide a first constant pull-down current to first transistor MN1 and second transistor MN2. When both first transistor MN1 and second transistor MN2 are enabled, the sum of the transistor currents is equal to the first pull-down current.

Third transistor MN3 is characterized by a third drive strength. When third transistor MN3 is enabled in response to the first intermediate signal received at the third transistor gate, the third drive strength is associated with the first intermediate signal. Fourth transistor MN4 is characterized by a fourth drive strength. When fourth transistor MN4 is enabled in response to the second intermediate signal received at the fourth transistor gate, the fourth drive strength is associated with the second intermediate signal. Second current source 916 is coupled to third transistor MN3 and fourth transistor MN4, both of which produced an inverted output with respect to the input. Second current source 916 is configured to provide a second constant pull-down current to third transistor MN3 and fourth transistor MN4. When both third transistor MN3 and fourth transistor MN4 are enabled, the sum of the transistor currents is equal to the second pull-down current.

For example, during a first operating period T₁ to T₂, the first pulse component 931 of the first differential input signal at node B is a positive-going pulse and the first non-zero voltage component 932 is at level high. First transistor MN1 is turned on upon receiving the first differential input signal at node B (e.g., first transistor gate). A first transistor current flows from the first transistor drain to the first transistor source. First transistor MN1 then output the first output signal at node C′. First transistor MN1 acts as an inverting amplifier, that is, voltage at node C′ V_{C′} is characterized by a voltage amplitude greater than that of the voltage at node B V_{B} and a reversed voltage polarity against V_{B}. At T₁, V_{B} transits from level low to level high and V_{C′} transits from level high to level low. For example, V_{B} may be around 100 mV and V_{C′} may be around −150 mV to −200 mV.

During the first operating period T₁ to T₂, the second pulse component 933 of the second differential input signal at node B′ is a negative-going pulse and a second non-zero voltage component 934 is at level low. Second transistor MN2 is turned on upon receiving the second differential input signal at node B′ (e.g., second transistor gate). A second transistor current flows from the second transistor drain to the second transistor source. Second transistor MN2 then output the second output signal at node C. Second transistor MN2 acts as an inverting amplifier, that is, voltage at node C V_{C} is characterized by a voltage amplitude greater than that of the voltage at node B′ V_{B′} and a reversed voltage polarity against V_{B′}. At T₁, V_{B′} transits from level high to level low and V_{C} transits from level low to level high. For example, V_{B′} may be around −100 mV and V_{C} may be around 150 mV to 200 mV. In this case, first transistor MN1 is stronger than second transistor MN2. Therefore, the first current flow through the first transistor drives the voltage at node D V_{D} to be lower than the voltage at node D′ V_{D′}.

Third transistor MN3 and fourth transistor MN4 are configured to retain the data value received at nodes D and D′ (also configured as outputs C′ and C). Third transistor MN3 is turned on upon receiving the first intermediate signal at the third switch input terminal (e.g., third transistor gate) node D. A third transistor current flows from the third transistor drain to third transistor source. Fourth transistor MN4 is turned on upon receiving the second intermediate signal at fourth switch input terminal (e.g., fourth transistor gate) node D′. A fourth transistor current flows from the fourth transistor drain to fourth transistor source. When the voltage at node D V_{D} is lower than the voltage at node D′ V_{D′}, third transistor MN3 is weaker than fourth transistor MN4. The fourth current flow through the fourth transistor further drives the voltage at node D V_{D} to be even lower than the voltage at node D′ V_{D′}. As such, the data value outputted at nodes C and C′ can be further retained during the first operating period T₁ to T₂.

During a second operating period T₂ to T₃, a third pulse component 935 of the first differential input signal at node B is a negative-going pulse and a third non-zero voltage component 936 is at level low. First transistor MN1 is turned on upon receiving the first differential input signal at node B (e.g., first transistor gate). A first transistor current flows from the first transistor drain to the first transistor source. First transistor MN1 then output the first output signal at node C′. First transistor MN1 acts as an inverting amplifier, that is, voltage at node C′ V_{C′} is characterized by a voltage amplitude greater than that of the voltage at node B V_{B} and a reversed voltage polarity against V_{B}. At T₂, V_{B} transits from level high to level low and V_{C′} transits from level low to level high. For example, V_{B} may be around −100 mV and V_{C′} may be around 150 mV to 200 mV.

During the second operating period T₂ to T₃, a fourth pulse component 937 of the second differential input signal at node B′ is a positive-going pulse and a fourth non-zero voltage component 938 is at level high. Second transistor MN2 is turned on upon receiving the second differential input signal at node B′ (e.g., second transistor gate). A second transistor current flows from the second transistor drain to the second transistor source. Second transistor MN2 then output the second output signal at node C. Second transistor MN2 acts as an inverting amplifier, that is, voltage at node C V_{C} is characterized by a voltage amplitude greater than that of the voltage at node B′ V_{B′} and a reversed voltage polarity against V_{B′}. At T₂, V_{B′} transits from level low to level high and V_{C} transits from level high to level low. For example, V_{B′} may be around 100 mV and V_{C} may be around −150 mV to −200 mV. In this case, first transistor MN1 is weaker than second transistor MN2. Therefore, the second current flow through the second transistor drives the voltage at node D′ V_{D′} to be lower than the voltage at node D V_{D}.

Third transistor MN3 is turned on upon receiving the first intermediate signal at the third switch input terminal (e.g., third transistor gate) node D. A third transistor current flows from the third transistor drain to third transistor source. Fourth transistor MN4 is turned on upon receiving the second intermediate signal at fourth switch input terminal (e.g., fourth transistor gate) node D′. A fourth transistor current flows from the fourth transistor drain to fourth transistor source. When the voltage at node D′ V_{D′} is lower than the voltage at node D V_{D}, third transistor MN3 is stronger than fourth transistor MN4. The third current flow through the third transistor MN3 further drives the voltage at node D′ V_{D′} to be even lower than the voltage at node D V_{D}. As such, the data value outputted at nodes C and C′ can be further retained.

To increase the immunity to interference, it is desirable for the latch circuit to have a voltage gain greater than 1. For example, when the voltage gain of the latch circuit is greater than or equal to 1.4, the latch circuit is likely to retain the captured data value and maintain either of the stable states. It is to be appreciated that a balanced circuit design is advantageous to improve the common-mode rejection. For example, first input resistor R₁ 907 and second input resistor R₂ 908 are of a matched impedance, first transistor MN1 and second transistor MN2 are of matched transconductance, first output resistor 913 and second output resistor 914 are of matched impedance, and third transistor MN3 and fourth transistor MN4 are of matched transconductance. The voltage gain of latch circuit at either of the stable state may be represented by the following equation (1):

Gain=gₘ₁R₁+gₘ₃(R₁+R₃) (1)

In equation (1), the term gₘ₁ is transconductance of the first transistor MN1 and the second transistor MN2, the term R₁ is the impedance of the first input resistor 907 and the second input resistor 908, the term gₘ₃ is the transconductance of the third transistor MN3 and the fourth transistor MN4, and the term R₃ is the impedance of the first output resistor 913 and second output resistor 914. It is to be appreciated that the voltage gain of the latch circuit may be configured by adjusting the electrical parameters of the circuit components. The more cascade structure (e.g., first cascade switch 911 and second cascade switch 912) configured in the latch circuit, the greater the voltage gain of the latch circuit. Theoretically, the number of cascade structure may be infinite. It is desirable for the latch circuit to have greater voltage gain to effectively overcome circuit mismatch and noise interference, etc. However, for conventional latch circuits, greater voltage gain entails input signals with higher voltage swings and higher power consumption to realize the data capture and storage.

As explained above, conventional latch circuits usually entail high-voltage input (e.g., above 500 mV) to switch from one stable state to another, which requires high power consumption and is not suited for high-speed analog signal processing. For conventional latch circuits, it is desirable for the latch circuit to respond to input signals with lower voltage swing (e.g., less than 300 mV) for high-speed signal processing and lower power consumption. The flipping amplitude ΔV_{B} at nodes B and B′ may be represented by the following equation (2):

$$Δ {V}_{B} = \frac{{I}_{r e f 1} {R}_{1}}{1 - g {m}_{1} {R}_{1}} \qquad ( 2 )$$

In equation (2), the term I_{ref1} is the current of the first current source 915, the term gₘ₁ is transconductance of the first transistor MN1 and the second transistor MN2, the term R₁ is the impedance of the first input resistor 907 and the second input resistor 908.

It is to be appreciated that a change in state of the first switch 909 and the second switch 910 causes a change in state of the first cascade switch 911 and second cascade switch 912. The flipping amplitude ΔV_{D} at nodes D and D′ may be represented by the following equation (3):

$$Δ {V}_{D} = \frac{{I}_{r e f 1} {R}_{1}}{1 - g {m}_{1} {R}_{1}} + {I}_{Ref 2} {R}_{3} \qquad ( 3 )$$

In equation (3), the term I_{ref1} is the current of the first current source 915, the term gₘ₁ is transconductance of the first transistor MN1 and the second transistor MN2, the term R₁ is the impedance of the first input resistor 907 and the second input resistor 908, the term I_{ref2} is the current of the second current source 916, and the term R₃ is the impedance of the first output resistor 913 and second output resistor 914. It is to be appreciated that the voltage amplitude at nodes D and D′ are amplified compared to the voltage amplitude at node B and B′ due to the amplification effect of first transistor MN1 and second transistor MN2. As such, the input signals with lower voltage swings at node B and B′ can enable the change of states of the latch circuit, and the cascade structure further ensures the stability of the latched signals. By stacking the cascade structures, the latch circuits disclosed in the present application advantageously increase the voltage gain of the latch circuit while reducing the flipping amplitude of the latch circuits, allowing for high-speed analog signal processing with enhanced system stability and lower power consumption.

The latch circuits described herein may be implemented on an IC, an analog IC, a mixed signal IC, an application specific integrated circuit (ASIC), a printed circuit board (PCB), an electronics device, etc. The latch circuits may also be fabricated with various IC process technologies such as CMOS, NMOS, PMOS, bipolar junction transistor (BJT), bipolar-CMOS (BiCMOS), silicon germanium (SiGe), gallioum arsenide (GaAs), etc. For example, latch circuits according to various embodiments of the present disclosure may be applied in a frequency divider circuit for high-speed processing and power saving.

While the above is a full description of the specific embodiments, various modifications, alternative constructions and equivalents may be used. Therefore, the above description and illustrations should not be taken as limiting the scope of the present invention which is defined by the appended claims.

What is claimed is:

1. A latch circuit comprising:
a first differential input terminal coupled to an isolation circuit for receiving a first differential input signal, the first differential input signal being characterized by a swing voltage of less than 300 mV;
a second differential input terminal coupled to the isolation circuit for receiving a second differential input signal;
a first switch comprising a first switch input terminal coupled to the first differential input terminal and a first output terminal;
a second switch comprising a second switch input terminal coupled to the second differential input terminal and a second output terminal;
a first input resistor coupled to the first differential input terminal and the first switch input terminal;
a second input resistor coupled to the second differential input terminal and the second switch input terminal;
a first output resistor coupled to the first output terminal;
a second output resistor coupled to the second output terminal;
a first cascade switch comprising a third switch input terminal and a first intermediate terminal, the third switch input terminal being coupled to the first output terminal, the first intermediate terminal being coupled to the second output terminal; and
a second cascade switch comprising a fourth switch input terminal and a second intermediate terminal, the fourth switch input terminal being coupled to the second output terminal, the second intermediate terminal being coupled to the first output terminal;
wherein:
the first differential input signal at the first differential input terminal comprises a first pulse component and a first non-zero voltage component, the first non-zero voltage component being attributed at least to the first switch and the first input resistor; and
a first output signal from the first output terminal comprises a first voltage component associated with the first switch and a second voltage component associated with the second cascade switch.

2. The circuit of claim 1 wherein the first switch is coupled to a first current source and the first cascade switch is coupled to a second current source.

3. The circuit of claim 1 wherein the first switch comprises a MOSFET transistor.

4. The circuit of claim 1 wherein the isolation circuit comprises a first isolation capacitor coupled to the first differential input terminal and a second isolation capacitor coupled to the second differential input terminal.

5. The circuit of claim 4 wherein isolation circuit is characterized by a first parasitic capacitance at the first differential input terminal and a second parasitic capacitance at the second differential input terminal.

6. The circuit of claim 1 wherein the first output signal is characterized by an amplitude of less than 400 mV and a substantially step shape.

7. The circuit of claim 1 wherein the first differential input terminal is directly coupled to the isolation circuit.

8. The circuit of claim 1 wherein the first output terminal is directly coupled to an amplifier.

9. The circuit of claim 1 wherein:
the second differential input signal at the second differential input terminal comprises a second pulse component and a second non-zero voltage component, the second non-zero voltage component being attributed to the second switch and the second input resistor; and
a second output signal from the second output terminal comprising a third voltage component associated with the second switch and a fourth voltage component associated with the first cascade switch.

10. An isolation circuit comprising:
a first input terminal for receiving a first input signal at a first amplitude;
a second input terminal for receiving a second input signal at a second amplitude, the first input signal and the second input signal being a differential pair;
a first isolation capacitor coupled to the first input terminal for generating a first isolation signal based on the first input signal;
a second isolation capacitor coupled to the second input terminal for generating a second isolation signal based on the second input signal;
a latch circuit coupled to the first isolation capacitor and the second isolation capacitor for receiving the first isolation signal and the second isolation signal and generating a first output signal and a second output signal in response to the first isolation signal and the second isolation signal, the latch circuit comprising:
a first differential input terminal configured to receive the first isolation signal, the first isolation signal comprising a first pulse component and a first non-zero voltage component, the first non-zero voltage component being attributed to the latch circuit;
a second differential input terminal configured to receive the second isolation signal, the second isolation signal comprising a second pulse component and a second non-zero voltage component, the second non-zero voltage component being attributed to the latch circuit;
a first switch coupled to the first differential input terminal and a first output terminal;
a second switch coupled to the second differential input terminal and a second output terminal, the second switch being cross-coupled with the first switch;
a first cascade switch coupled to the first switch, the first cascade switch comprising a third switch input terminal coupled between the first switch and the first output terminal; and
a second cascade switch coupled to the second switch, the second cascade switch comprising a fourth switch input terminal coupled between the second switch and the second output terminal, the second cascade switch being cross-coupled with the first cascade switch;
wherein:
a first output signal from the first output terminal comprises a first voltage component associated with the first switch and a second voltage component associated with the second cascade switch; and
a second output signal from the second output terminal comprises a third voltage component associated with the second switch and a fourth voltage component associated with the first cascade switch.

11. The isolation circuit of claim 10, further comprising:
a first input resistor coupled to the first differential input terminal and the first switch input terminal, the first input resistor is configured to provide a first direct current component to the first isolation signal; and
a second input resistor coupled to the second differential input terminal and the second switch input terminal, the second input resistor is configured to provide a second direct current component to the second isolation signal.

12. The isolation circuit of claim 10, wherein:
the first switch is enabled in response to the first isolation signal received at the first differential input terminal, a first drive strength of the first switch is associated with the first isolation signal; and
the second switch is enabled in response to the second isolation signal received at the second differential input terminal, a second drive strength of the second switch is associated with the second isolation signal.

13. The isolation circuit of claim 10, wherein:
the first cascade switch is configured to receive a first intermediate signal at the third switch input terminal, a third drive strength of the first cascade switch is associated with the first intermediate signal; and
the second cascade switch is configured to receive a second intermediate signal at the fourth switch input terminal, a fourth drive strength of the second cascade switch is associated with the second intermediate signal.

14. The isolation circuit of claim 10, wherein:
the first cascade switch further comprises a first intermediate terminal coupled to the second output terminal; and
the second cascade switch further comprises a second intermediate terminal coupled to the first output terminal.

15. The isolation circuit of claim 10, wherein:
the first output signal from the first output terminal is associated with the fourth drive strength of the second cascade switch; and
the second output signal from the second output terminal is associated with the third drive strength of the first cascade switch.

16. The isolation circuit of claim 10, wherein the latch circuit further comprises:
a first current source coupled to the first switch, the first current source being configured to provide a first pull-down current to the first switch and the second switch; and
a second current source coupled to the first cascade switch, the second current source being configured to provide a second pull-down current to the first cascade switch and the second cascade switch.

17. The isolation circuit of claim 10, wherein:
the first isolation signal is characterized by a swing voltage of less than 300 mV; and
the first output signal is characterized by an amplitude of less than 400 mV.

18. A latch circuit comprising:
a first differential input terminal coupled to an isolation circuit for receiving a first differential input signal, the first differential input signal being characterized by a swing voltage of less than 300 mV;
a second differential input terminal coupled to the isolation circuit for receiving a second differential input signal;
a first switch comprising a first transistor having a first transistor gate, a first transistor drain, and a first transistor source, the first transistor gate being coupled to the first differential input terminal, and the first transistor drain being coupled to a first output terminal;
a second switch comprising a second transistor having a second transistor gate, a second transistor drain, and a second transistor source, the second transistor gate being coupled to the second differential input terminal, and the second transistor drain being coupled to a second output terminal;
a first input resistor coupled to the first differential input terminal and the first transistor gate;
a second input resistor coupled to the second differential input terminal and the second transistor gate;
a first cascade switch comprising a third transistor having a third transistor gate, a third transistor drain, and a third transistor source, the third transistor gate being coupled to the first output terminal, and the third transistor drain being coupled to the second output terminal;
a second cascade switch comprising a fourth transistor having a fourth transistor gate, a fourth transistor drain, and a fourth transistor source, the fourth transistor gate being coupled to the second output terminal, and the fourth transistor drain being coupled to the first output terminal;
a first output resistor coupled to the first output terminal and the third transistor gate; and
a second output resistor coupled to the second output terminal and the fourth transistor gate;
wherein:
the first differential input signal at the first differential input terminal comprises a first pulse component and a first non-zero voltage component, the first non-zero voltage component being attributed at least to the first switch and the first input resistor; and
a first output signal from the first output terminal comprises a first voltage component associated with the first switch and a second voltage component associated with the second cascade switch.

19. The latch circuit of claim 18, wherein:
the first transistor is cross-coupled with the second transistor such that the first transistor drain is coupled to the second transistor gate and the second transistor drain is coupled to the first transistor gate; and
the third transistor is cross-coupled with the fourth transistor such that the third transistor gate is coupled to the fourth transistor drain and the fourth transistor gate is coupled to the third transistor drain.

20. The latch circuit of claim 18, wherein:
the first transistor source and the second transistor source are both coupled to a first current source, the first current source is configured to provide a first pull-down current to the first transistor and the second transistor; and
the third transistor source and the fourth transistor source are both coupled to a second current source, the second current source is configured to provide a second pull-down current to the third transistor and the fourth transistor.
